(19) United States
(12) Patent Application Publication
(10) Pub. No.: US 2025/0072067 A1
(43) Pub. Date: Feb. 27, 2025

(54) SEMICONDUCTOR STRUCTURE AND METHOD FOR FORMING THE SAME

(71) Applicant: TAIWAN SEMICONDUCTOR MANUFACTURING COMPANY LTD., HSINCHU (TW)

(72) Inventors: SHIH-CHENG CHEN, NEW TAIPEI CITY (TW); WEN-TING LAN, HSINCHU CITY (TW); JUNG-HUNG CHANG, CHANGHUA COUNTY (TW); CHIA-CHENG TSAI, HSINCHU (TW); KUO-CHENG CHIANG, HSINCHU COUNTY (TW)

(21) Appl. No.: 18/455,654

(22) Filed: Aug. 25, 2023

(51) Int. Cl. H01L 29/06; H01L 21/8238; H01L 27/092; H01L 29/423; H01L 29/66; H01L 29/775

(52) U.S. Cl. CPC H01L 29/0673; H01L 21/823807; H01L 21/823814; H01L 21/823878; H01L 27/092; H01L 29/42392; H01L 29/66439; H01L 29/66545; H01L 29/775

(57) ABSTRACT

A semiconductor structure includes an isolation structure in a substrate, a metal gate structure over the substrate and a portion of the isolation structure, a spacer at sidewalls of the metal gate structure, epitaxial source/drain structure at two sides of the metal gate structure, and a protection layer over the isolation structure. The protection layer and the spacer include a same material.

### BACKGROUND

As the semiconductor industry develops smaller and smaller nanoscale products and related processes in pursuit of greater device density, higher performance, and lower costs, challenges of downscaling both design and fabrication have led to development of three-dimensional designs, such as multi-gate field-effect transistors (FET), including a fin FET (FinFET) and a gate-all-around (GAA) FET. In a FinFET, a gate electrode is positioned adjacent to three side surfaces of a channel region with a gate dielectric layer interposed therebetween. Because such gate structure surrounds a fin on three sides, the FinFET essentially has three gates controlling a current through the fin or the channel region. However, a fourth side, that is, a bottom part of the channel region, is positioned far away from the gate electrode and thus is not under close gate control. In contrast to a FinFET, a GAA FET includes an arrangement wherein all side surfaces of the channel region are surrounded by the gate electrode, allowing fuller depletion in the channel region and resulting in fewer short-channel effects due to a steeper sub-threshold current swing (SS) and smaller drain-induced barrier lowering (DIBL).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart representing a method for forming a semiconductor structure according to aspects of the present disclosure.

FIGS. 2A to 13B are perspective views of a semiconductor structure at various fabrication stages constructed according to aspects of one or more embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

This description of illustrative embodiments is intended to be read in connection with the accompanying drawings, which are to be considered part of the entire written description. In the description of embodiments disclosed herein, any reference to direction or orientation is merely intended for convenience of description and is not intended in any way to limit the scope of the present disclosure. Relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected” refer to a relationship wherein structures are secured or attached to one another either directly or indirectly through intervening structures, as well as both movable or rigid attachments or relationships, unless expressly described otherwise. Moreover, the features and benefits of the disclosure are illustrated by reference to the embodiments. Accordingly, the disclosure expressly should not be limited to such embodiments illustrating some possible non-limiting combination of features that may exist alone or in other combinations of features; the scope of the disclosure being defined by the claims appended hereto.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The term “nanosheet” refers to atomic, molecular or macromolecular particles typically having a thickness in a range of approximately 1 to 100 nanometers and a width greater than the thickness. For example, the width may be at least twice the thickness, but the disclosure is not limited thereto. Typically, novel and differentiating properties and functions of nanosheet components are observed or developed at a critical length scale of under 100 nm. In some embodiments, “nanosheet” components can also be referred to as “nano-slab,” “nano-ring” or “multi-bridge channel” components.

In some embodiments, a method for forming a multi-gate FET device is provided. The method may include following operations. After forming a sacrificial gate structure over nanosheet stack fins, recesses are formed for accommodating epitaxial source/drain structures. Etching operations are often used to form the recesses, but recess profiles are difficult to control due to high aspect ratios. In some comparative approaches, an isolation structure that is used to separate the nanosheet stack fins may be consumed during the forming of the recesses. The isolation loss issue may cause a collapse of the sacrificial gate structure, also referred to as a poly collapse. Further, when the isolation structure is consumed to expose semiconductor materials adjacent thereto, unwanted epitaxial structure may be mistakenly formed during forming of the epitaxial source/drain structures.

The present disclosure therefore provides a semiconductor structure and a method for forming the same. In some embodiments, the method includes forming a protection layer over an isolation structure. As a result, the isolation structure is protected from consumption or damage during forming of a recess for accommodating epitaxial source/drain structures. Accordingly, an isolation loss issue is mitigated, and potential risks of poly collapse and formation of an improper epitaxial structure are reduced.

The embodiments described herein may be employed in design and/or fabrication of any type of integrated circuit, or portion thereof, which may include any of a plurality of various devices and/or components such as a static random access memory (SRAM) and/or other logic circuits, passive components such as resistors, capacitors, and inductors, and active components such as P-channel field-effect transistors (PFETs), N-channel FETs (NFETs), metal-oxide-semiconductor field-effect transistors (MOSFETs), complementary metal-oxide-semiconductor (CMOS) transistors, bipolar transistors, high voltage transistors, high frequency transistors, Omega-gate (Ω-gate) devices, or Pi-gate (H-gate) devices, as well as strained-semiconductor devices, silicon-on-insulator (SOI) devices, partially-depleted SOI (PD-SOI) devices, fully-depleted SOI (FD-SOI) devices, other memory cells, or other devices known in the art. One of ordinary skill may recognize other embodiments of semiconductor devices and/or circuits, including the design and fabrication thereof, which may benefit from aspects of the present disclosure.

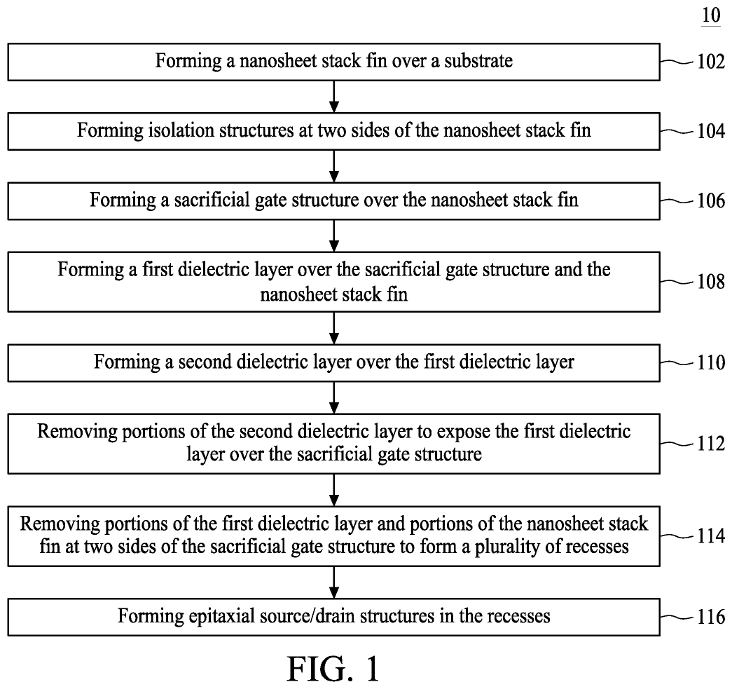

FIG. 1 is a flowchart representing a method for forming a semiconductor structure 10 according to aspects of the present disclosure. The method 10 includes a number of operations (102, 104, 106, 108, 110, 112, 114 and 116). The method 10 will be further described according to one or more embodiments. It should be noted that the operations of the method 10 may be rearranged or otherwise modified within the scope of the various aspects. It should be further noted that additional processes may be provided before, during, and after the method 10, and that some other processes may just be briefly described herein. Thus, other implementations are possible within the scope of the various aspects described herein.

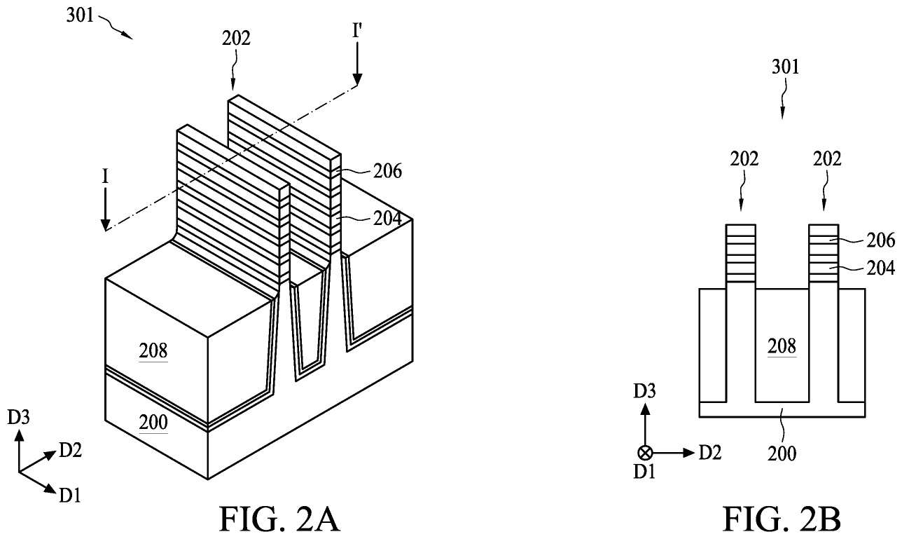

FIGS. 2A to 13B are schematic views illustrating a semiconductor structure at various fabrication stages constructed according to aspects of one or more embodiments of the present disclosure. For example, FIGS. 2A and 2B illustrate an intermediate semiconductor structure 301 according to some embodiments corresponding to operation 102 and operation 104. Further, FIG. 2B is a cross-sectional view taken along a line I-I′ of FIG. 2A. In operation 102. a nanosheet stack fin 202 is formed over a substrate 200. The nanosheet stack fin 202 includes a plurality of nanosheets extending in a first direction D1. In some embodiments, the substrate 200 may be a semiconductor substrate such as a silicon substrate. The substrate 200 may also include other semiconductors such as germanium (Ge), silicon carbide (SiC), silicon germanium (SiGe), or diamond. Alternatively, the substrate 200 may include a compound semiconductor and/or an alloy semiconductor. The substrate 200 may include various layers, including conductive or insulating layers formed on a semiconductor substrate. The substrate 200 may include various doping configurations depending on design requirements as is known in the art. For example, different doping profiles (e.g., n wells or p wells) may be formed on the substrate 200 designed for different device types (e.g., n-type field effect transistors (NFET) or p-type field effect transistors (PFET)). The suitable doping may include ion implantation of dopants and/or diffusion processes.

In some embodiments, a plurality of alternating semiconductor layers 204 and 206 are formed over the substrate 200. The alternating semiconductor layers 204 and 206 may be used to selectively process some of the layers. Accordingly, various compositions of the semiconductor layers 204 and 206 may have different oxidation rates, etchant sensitivity, and/or other differing properties. The semiconductor layers 204 and 206 may have thicknesses chosen based on device performance considerations. In some embodiments, the semiconductor layers 204 are substantially uniform in thickness, and the semiconductor layers 206 are substantially uniform in thickness.

In some embodiments, either of the semiconductor layers 204 and 206 may include Si. In some embodiments, either of the semiconductor layers 204 and 206 may include other materials such as Ge, a compound semiconductor such as silicon carbide (SiC), gallium arsenide (GaAs), gallium phosphide (GaP), indium phosphide (InP), indium arsenide (InAs), and/or indium antimonide (InSb), an alloy semiconductor such as SiGe, GaAsP, AlInAs, AlGaAs, InGaAs, GaInP, and/or GaInAsP, or combinations thereof. In some embodiments, the semiconductor layers 204 and 206 may be undoped or substantially dopant-free, where, for example, no doping is performed during an epitaxial growth process. Alternatively, the semiconductor layers 204 and 206 may be doped. For example, the semiconductor layers 204 or 206 may be doped with a p-type dopant such as boron (B), aluminum (Al), In, or Ga for forming a p-type channel, or an n-type dopant such as P, As, or Sb for forming an n-type channel.

Still referring to FIGS. 2A and 2B, the nanosheet stack fin 202 may be fabricated using suitable operations including photolithography and etch operations. In some embodiments, forming the nanosheet stack fin 202 may further include a trim process to decrease a width and/or a height of the nanosheet stack fin 202. The trim process may include wet or dry etching processes. The height and the width of the nanosheet stack fin 202 may be chosen based on device performance considerations. Further, the nanosheet stack fin 202 can extend along the first direction D1 as shown in FIGS. 2A and 2B. Additionally, the nanosheet stack fins 202 are arranged in a second direction D2, wherein the second direction D2 is not parallel to the first direction D1.

Still referring to FIGS. 2A and 2B, in some embodiments, in operation 104, isolation structures are formed at two sides of the nanosheet stack fins 202. In some embodiments, gaps between nanosheet stack fins 202 are filled with a dielectric material for forming shallow trench isolations (STIs) 208 interposing the nanosheet stack fins 202. In some embodiments, the STIs 208 are recessed, thereby exposing portions of sidewalls of the nanosheet stack fins 202. In some embodiments, the dielectric material used to fill the gaps and to form the STIs 208 may include silicon oxide (SiO), silicon nitride (SiN), silicon oxynitride (SiON), fluorine-doped silicate glass (FSG), a low-k dielectric, combinations thereof, and/or other suitable materials known in the art.

In some embodiments, a cap layer or a liner (not shown) may be conformally formed over the nanosheet stack fins 202. Accordingly, tops and the sidewalls of the nanosheet stack fins 202 that are exposed through the STIs 208 are covered by the cap layer. In some embodiments, the cap layer includes dielectric materials such as SiN, SiON, silicon carbonitride (SiCN), silicon oxycarbonitride (SiOCN), or other appropriate material. In other embodiments, the cap layer may include silicon germanium (SiGe).

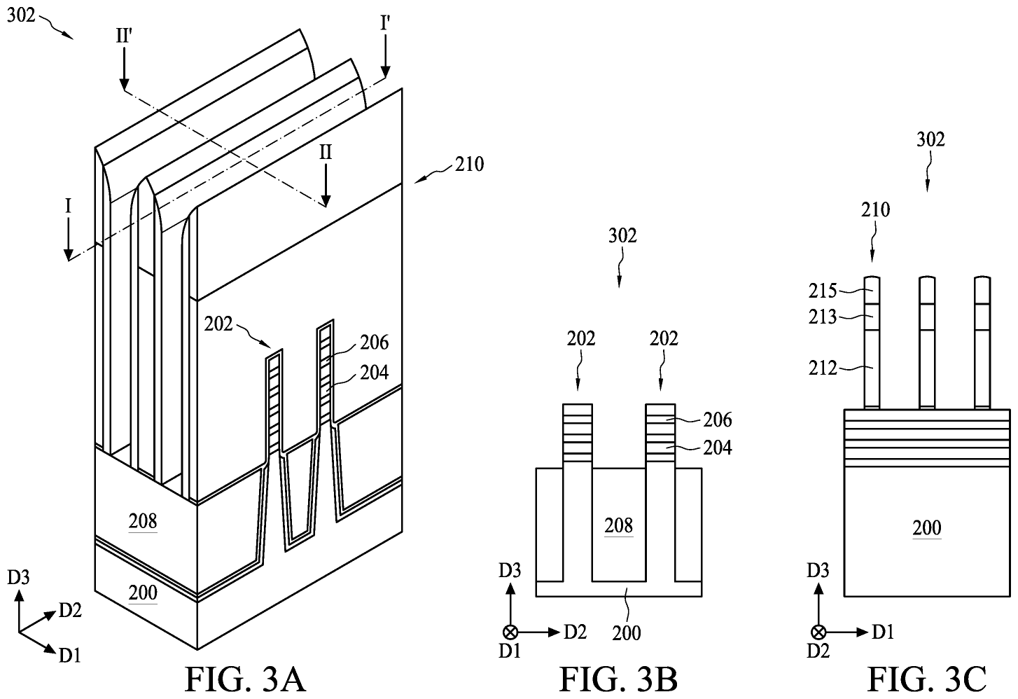

Please refer to FIGS. 3A, 3B and 3C, which are schematic drawings of an intermediate semiconductor structure 302 according to some embodiments corresponding to operation 106. Further, FIG. 3B is a cross-sectional view taken along a line I-I′ of FIG. 3A, and FIG. 3C is a cross-sectional view taken along a line II-II′ of FIG. 3A. In operation 106, a sacrificial gate structure 210 is disposed over the nanosheet stack fins 202 and the substrate 200. In some embodiments, a polysilicon layer 212 is formed over the substrate 200 and the nanosheet stack fins 202. A patterned hard mask is formed over the polysilicon layer 212. In some embodiments, the patterned hard mask may be a patterned multiple hard mask. For example, the patterned multiple hard mask may include a first layer 213 and a second layer 215, but the disclosure is not limited thereto. In some embodiments, the first layer 213 and the second layer 215 may include different dielectric materials. The polysilicon layer 212 is patterned through the patterned hard mask 213/215, thereby forming the sacrificial gate structure 210. The sacrificial gate structure 210 may be replaced at a later processing stage by a metal gate electrode (MG) as discussed below. As shown in FIG. 3A, the sacrificial gate structure 210 extends along the second direction D2. Additionally, the sacrificial gate structures 210 may be arranged along the first direction D1. Each of the sacrificial gate structures 210 is at least partially disposed over the nanosheet stack fins 202. Additionally, each of the sacrificial gate structures 210 covers portions of the STIs 208.

In some embodiments, portions of the cap layer that are exposed through the sacrificial gate structures 210 may be removed, thereby exposing the semiconductor layers 204 and 206, as shown in FIG. 3B.

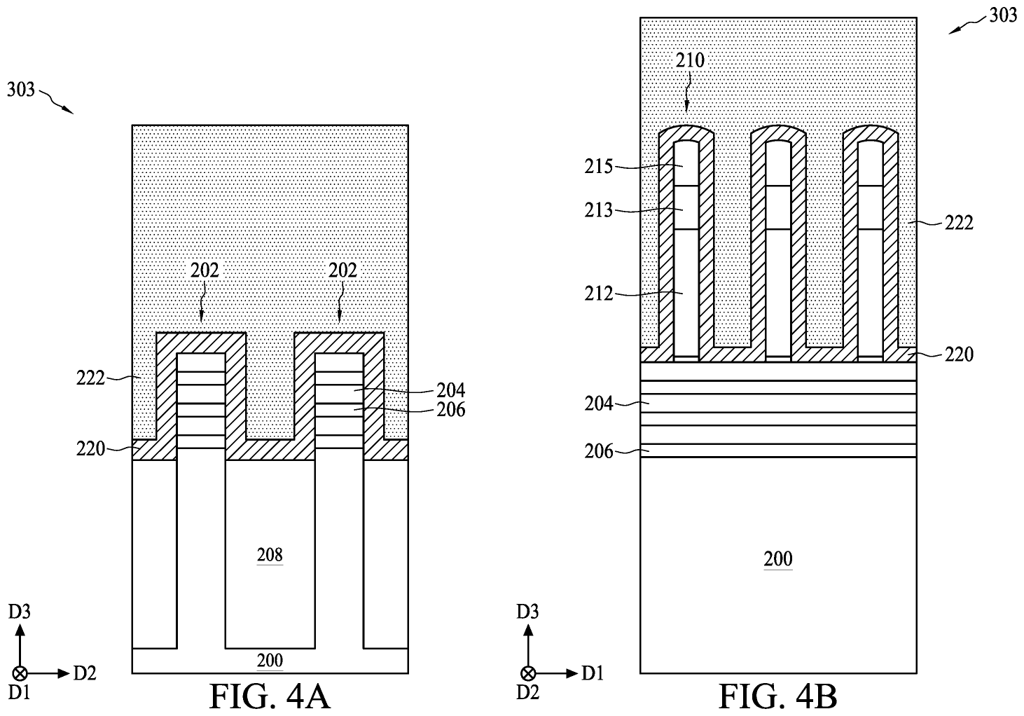

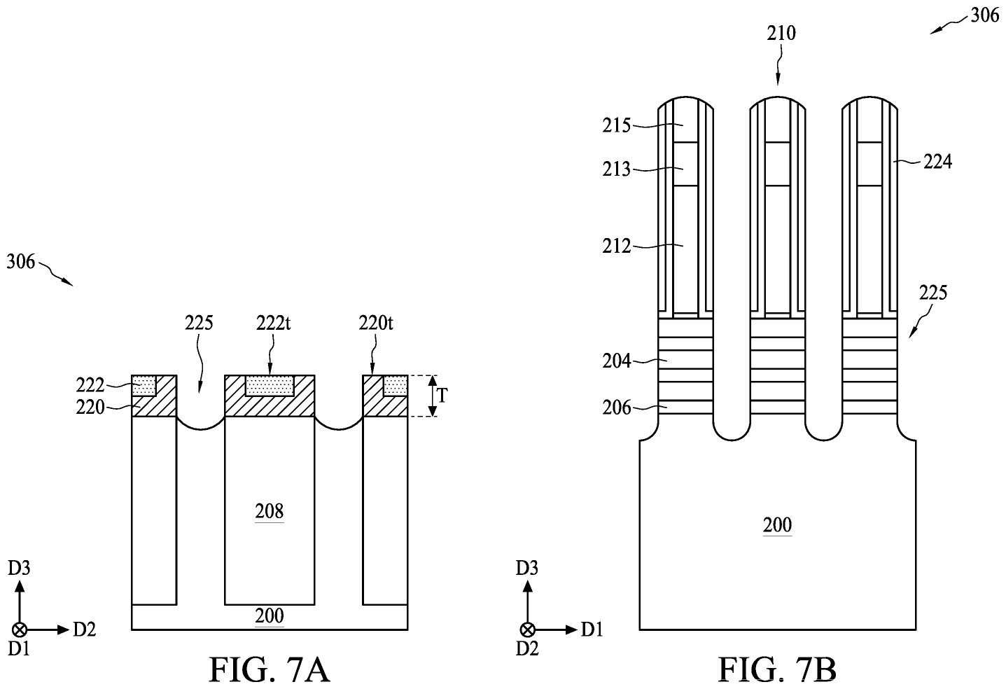

Please refer to FIGS. 4A and 4B, which are cross-sectional views of an intermediate semiconductor structure 303 according to some embodiments corresponding to operation 108 and operation 110 of the present disclosure. In operation 108, a first dielectric layer 220 is formed over the sacrificial gate structures 210 and the nanosheet stack fins 202. As shown in FIGS. 4A and 4B, the first dielectric layer 220 is conformally formed; therefore, sidewalls and top surfaces of nanosheet stack fins 202 are covered by the first dielectric layer 220. Also, sidewalls and top surfaces of the sacrificial gate structures 210 are covered by the first dielectric layer 220. In some embodiments, the first dielectric layer 220 is made of silicon nitride (SIN), silicon carbide (SiC), silicon oxycarbonitride (SiOCN), silicon carbonitride (SiCN), SiC or any suitable material, but the disclosure is not limited thereto. In some embodiments, the first dielectric layer 220 may be a single layer. In other embodiments, the first dielectric layer 220 may be a multilayer. For example, the first dielectric layer 220 may be a bilayer, as shown in FIG. 7B.

Still referring to FIGS. 4A and 4B, in operation 110, a second dielectric layer 222 is formed over the first dielectric layer 220. The second dielectric layer 222 includes a material different from that of the first dielectric layer 220. In some embodiments, the materials of the first dielectric layer 220 and the second dielectric layer 222 have different etchant sensitivities. For example, the second dielectric layer 222 may include silicon oxide. A thickness of the second dielectric layer 222 is greater than a thickness of the first dielectric layer 220. In some embodiments, gaps between nanosheet stack fins 202 and gaps between the sacrificial gate structures 210 are filled with the second dielectric layer 222.

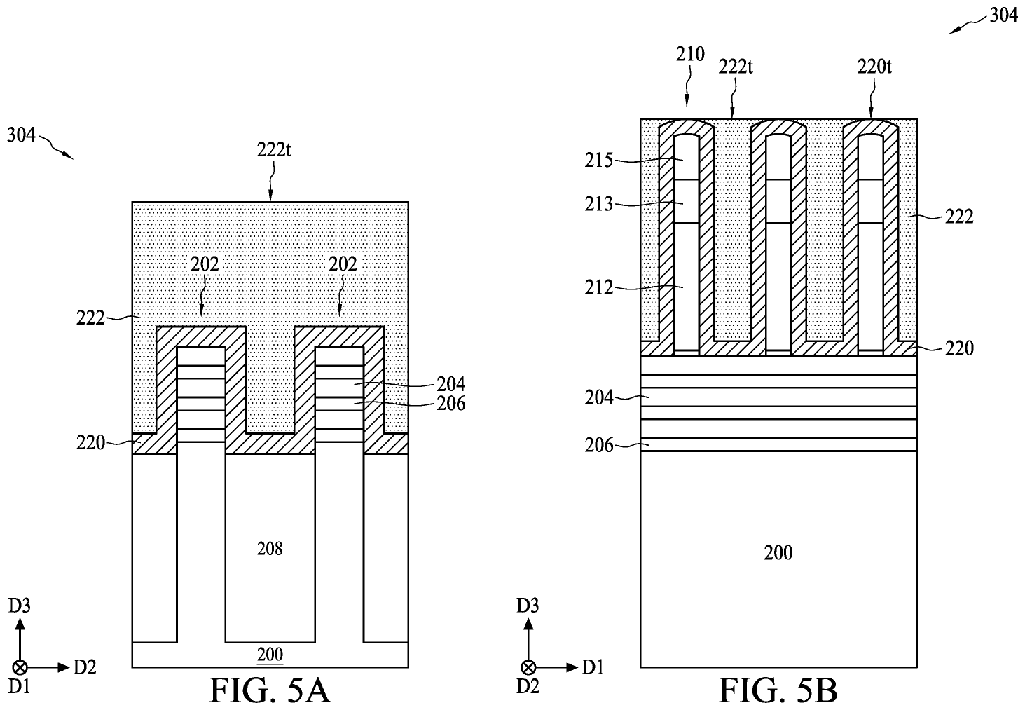

Please refer to FIGS. 5A and 5B, which are cross-sectional views of an intermediate semiconductor structure 304 according to some embodiments corresponding to operation 112 of the present disclosure. In operation 112, portions of the second dielectric layer 222 are removed to expose portion of the first dielectric layer 220 over the sacrificial gate structures 210. In some embodiments, the removal of the portions of the second dielectric layer 222 includes performing a planarization such as a chemical mechanical polishing (CMP) operation on the second dielectric layer 222. Accordingly, a top surface 222t of the second dielectric layer 222 is lowered to expose a top surface 220t of the first dielectric layer 220, as shown in FIG. 5B. In such embodiments, the sidewalls of the sacrificial gate structures 210 and portions of the first dielectric layer 220 over the sidewalls of the sacrificial gate structure 210 are still embedded in the second dielectric layer 222. Further, the nanosheet stack fins 202 are entirely embedded within the second dielectric layer 222, as shown in FIG. 5A. In other words, the top surface 222t of the second dielectric layer 222 is level with the top surface 220t of the first dielectric layer 220, while the top surface 222t of the second dielectric layer 222 is at a level higher than that of top surfaces of the nanosheet stack fins 202.

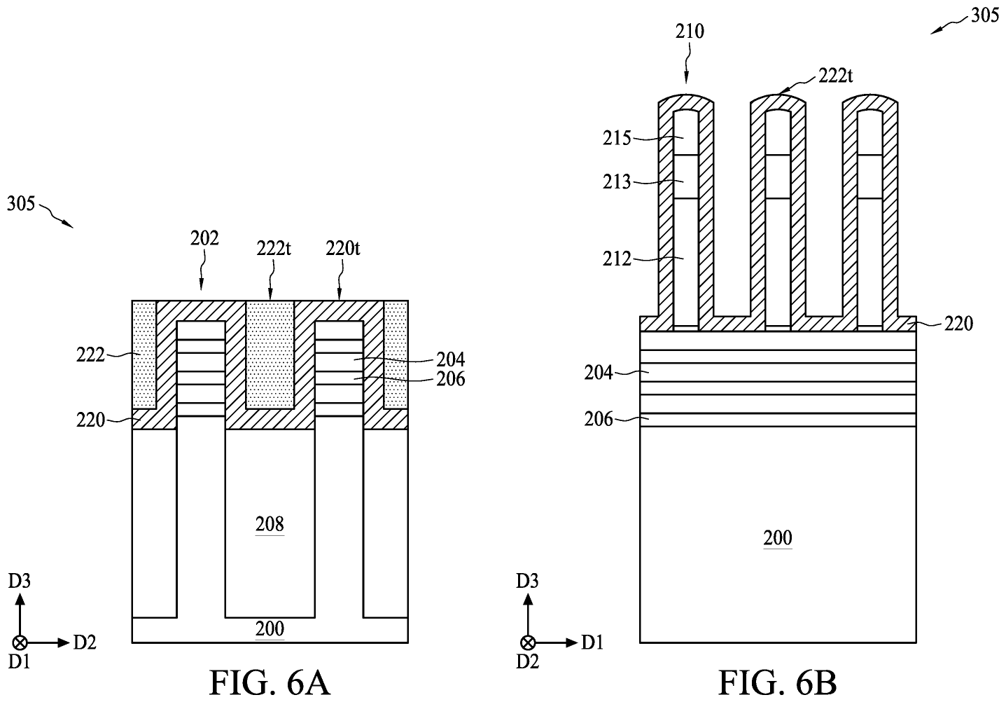

Please refer to FIGS. 6A and 6B, which are cross-sectional views of an intermediate semiconductor structure 305 according to some embodiments corresponding to operation 112 of the present disclosure. In operation 112, other portions of the second dielectric layer 222 are removed to expose portion of the first dielectric layer 220 over the sidewalls of the sacrificial gate structures 210. In some embodiments, the removal of the portions of the second dielectric layer 222 includes performing an etch-back operation on the second dielectric layer 222. Accordingly, another top surface 222t of the second dielectric layer 222 is lowered. As shown in FIG. 6A, the top surface 222t of the second dielectric layer 222 is level with the top surface 220t of the first dielectric layer 220 over the nanosheet stack fins 202. However, the portions of the first dielectric layer 220 over the sidewalls of the nanosheet stack fins 202 are still covered by the second dielectric layer 222. As shown in FIG. 6B, the portions of the first dielectric layer 220 over the tops and sidewalls of the sacrificial gate structures 210 are exposed.

Please refer to FIGS. 7A and 7B, which are cross-sectional views of an intermediate semiconductor structure 306 according to some embodiments corresponding to operation 114 of the present disclosure. In operation 114, portions of the first dielectric layer 220 are removed to form spacers 224 over the sidewalls of the sacrificial gate structures 210. In some embodiments, the removal of the portions of the first dielectric layer 220 includes using another etch-back operation. In some embodiments, the portions of first dielectric layer 220 over the tops of the nanosheet stack fins 202 are removed, thereby exposing the nanosheet stack fins 202. In some embodiments, portions of the second dielectric layer 222 are also removed in the etch-back operation. Consequently, the top surface 222t of the second dielectric layer 222 is further lowered to be level with the portions of the top surface 220t of the first dielectric layer 220 over the nanosheet stack fin 202. In some embodiments, a remaining portion of the first dielectric layer 220 and a remaining portion of the second dielectric layer 222 have a thickness T, and the thickness T is between approximately 5 nanometers and approximately 30 nanometers.

Still referring to FIGS. 7A and 7B, in some embodiments, in operation 114, portions of the nanosheet stack fins 202 at two sides of the sacrificial gate structures 210 are removed to form a plurality of recesses 225. As shown in FIG. 7A, a bottom of the recess 225 is lower than the top surface 220t of the first dielectric layer 220, and lower than the top surface 222t of the second dielectric layer 222. As shown in FIG. 7B, the bottom of the recess 225 is lower than a bottom surface of a lowest semiconductor layer 206 of the nanosheet stack fin 202. It should be noted that during the removal of the portions of the nanosheet stack fins 202 to form the recesses 225, the first dielectric layer 220 and the second dielectric layer 222 combine to protect the STIs 208. Accordingly, an isolation loss issue is mitigated.

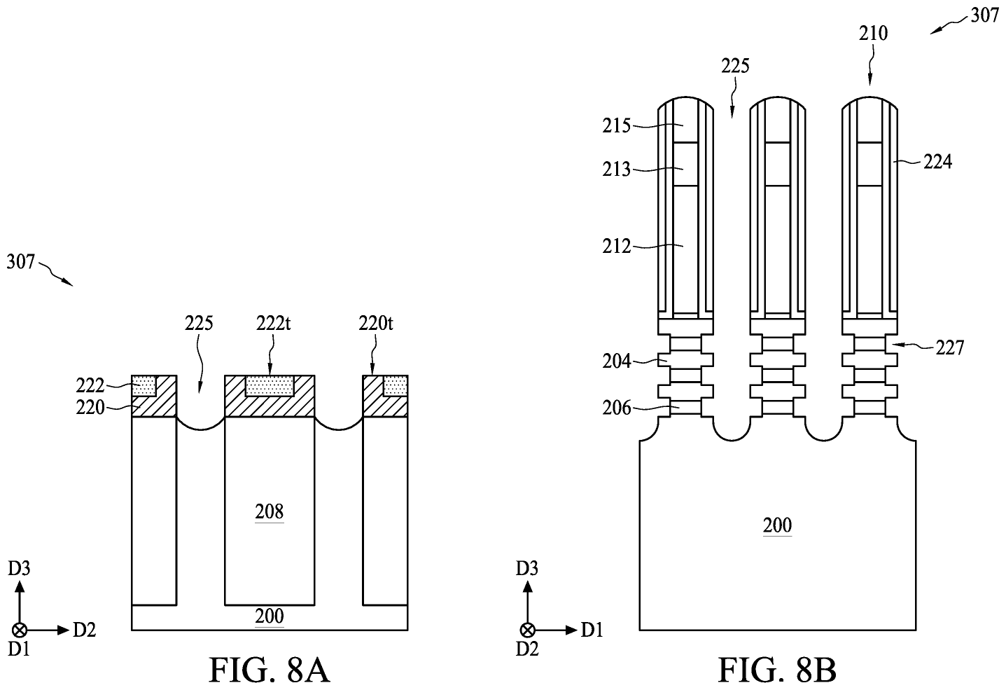

Please refer to FIGS. 8A and 8B, which are cross-sectional views of an intermediate semiconductor structure 307 according to some embodiments of the present disclosure. In some embodiments, the exposed semiconductor layers 206 of the nanosheet stack fin 202 are partially removed, thereby forming a plurality of notches 227 between the remaining semiconductor layers 204.

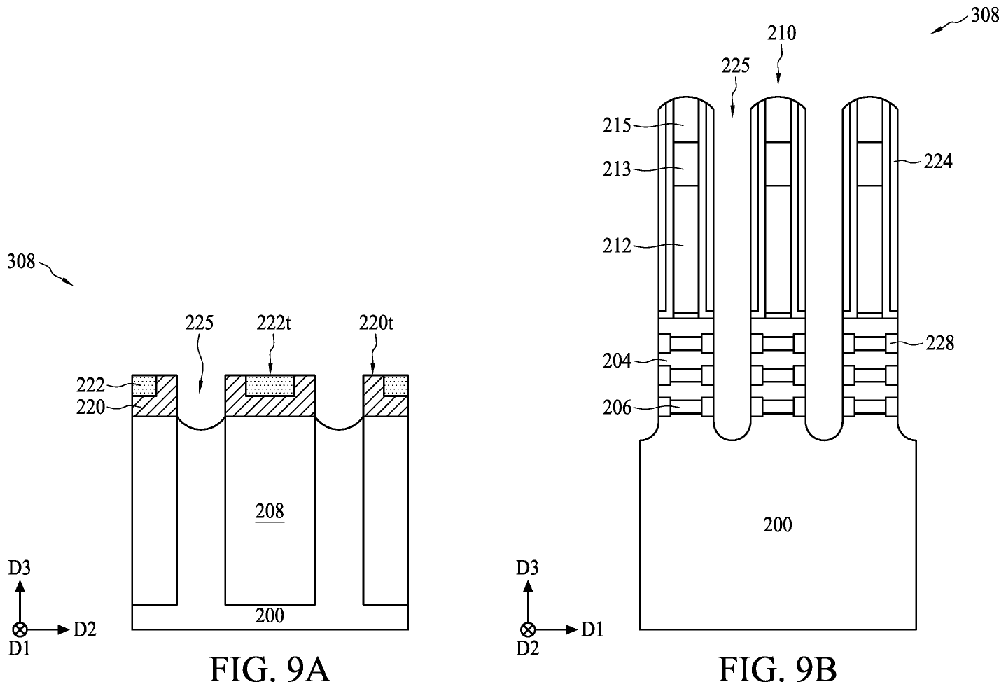

Please refer to FIGS. 9A and 9B, which are cross-sectional views of an intermediate semiconductor structure 308 according to some embodiments of the present disclosure. An insulating layer is formed to fill the notches 227. In some embodiments, the insulating layer include SiOCN, but the disclosure is not limited thereto. Subsequently, portions of the insulating layer may be removed, thereby forming inner spacers 228.

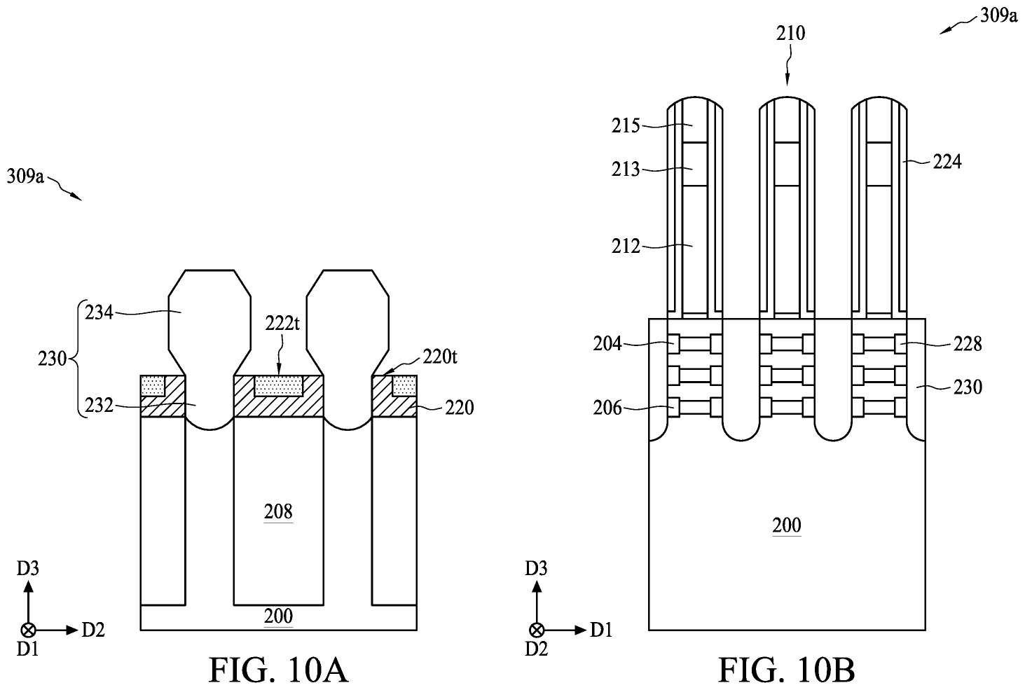

Please refer to FIGS. 10A and 10B, which are cross-sectional views of an intermediate semiconductor structure 309a according to some embodiments corresponding to operation 116 of the present disclosure. In operation 116, epitaxial source/drain structures 230 are formed in the recesses 225 at the two sides of the sacrificial gate structure 210. The source/drain structures 230 may be a source or a drain, individually or collectively depending upon the context. In some embodiments, the epitaxial source/drain structures 230 can be relatively higher than the nanosheet stack fin 202. In some embodiments, the epitaxial source/drain structures 230 are formed by an epitaxial (epi) process. In addition, a lattice constant of the strained material may be different from a lattice constant of the substrate 200. Accordingly, the epitaxial source/drain structures 230 serve as stressors that improve carrier mobility.

Still referring to FIG. 10A, in some embodiments, the epitaxial source/drain structures 230 are formed from the substrate 200 exposed through the bottoms of the recesses 225. Because the bottoms of the recesses 225 are lower than the top surface 222t of the second dielectric layer 222 and the top surface 220t of the first dielectric layer 220, a growth of the epitaxial structure is confined during the epitaxial process. Accordingly, a portion of the epitaxial source/drain structure 230 is surrounded by the first dielectric layer 220 and the second dielectric layer 222. Such portion of the epitaxial source/drain structure 230 may be referred to as a root portion 232, and a width of the root portion 232 is equal to a width of the recesses 225. In some embodiments, the epitaxial growth continues and the epitaxial source/drain structure 230 grows to be higher than the top surfaces 220t and 222t of the first and second dielectric layers 220 and 222. The portion that protrudes higher than the top surfaces 220t and 222t of the first and second dielectric layers 220 and 222 may be referred to as a function portion 234 that renders stress to a channel region of a device to be formed. In such embodiments, a width of the function portion 234 is greater than the width of the root portion 232.

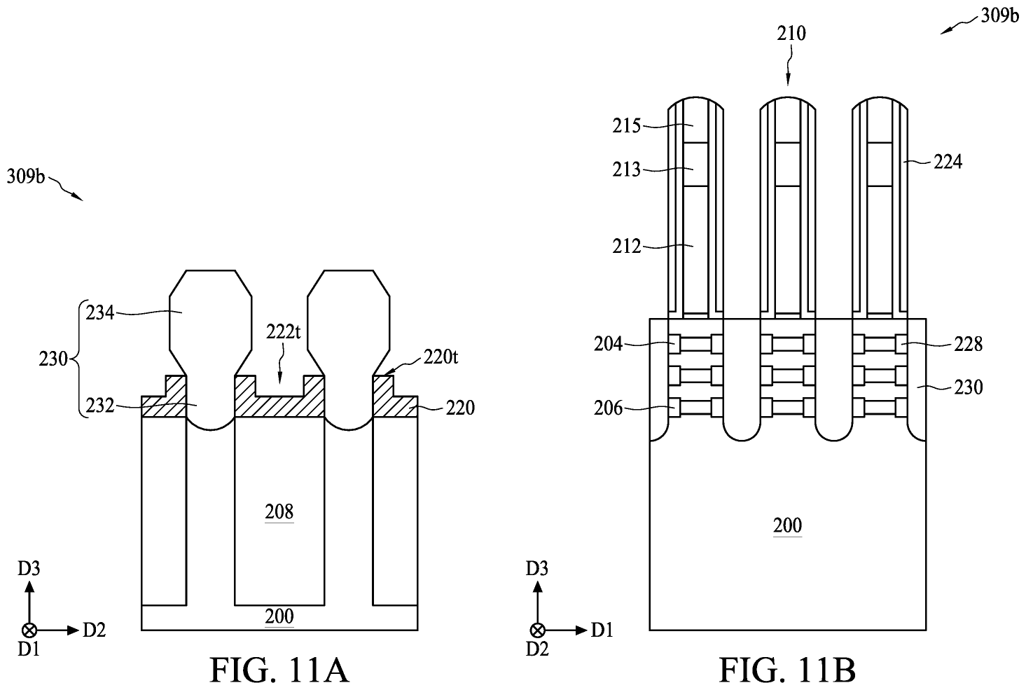

Please refer to FIGS. 11A and 11B, which are cross-sectional views of an intermediate semiconductor structure 309b according to some embodiments corresponding to operation 116 of the present disclosure. In some embodiments, a cleaning operation is performed to remove native oxides from the recesses 225 prior to the forming of the epitaxial source/drain structures 230. In some embodiments, the second dielectric layer 222 may be consumed by the cleaning operation. In some embodiments, the second dielectric layer 222 may be removed from the recesses 225, as shown in FIG. 11A. Subsequently, the epitaxial source/drain structures 230 are formed in the recesses 225. The forming of the epitaxial source/drain structures 230 is similar to that described above; therefore, details thereof are omitted for brevity.

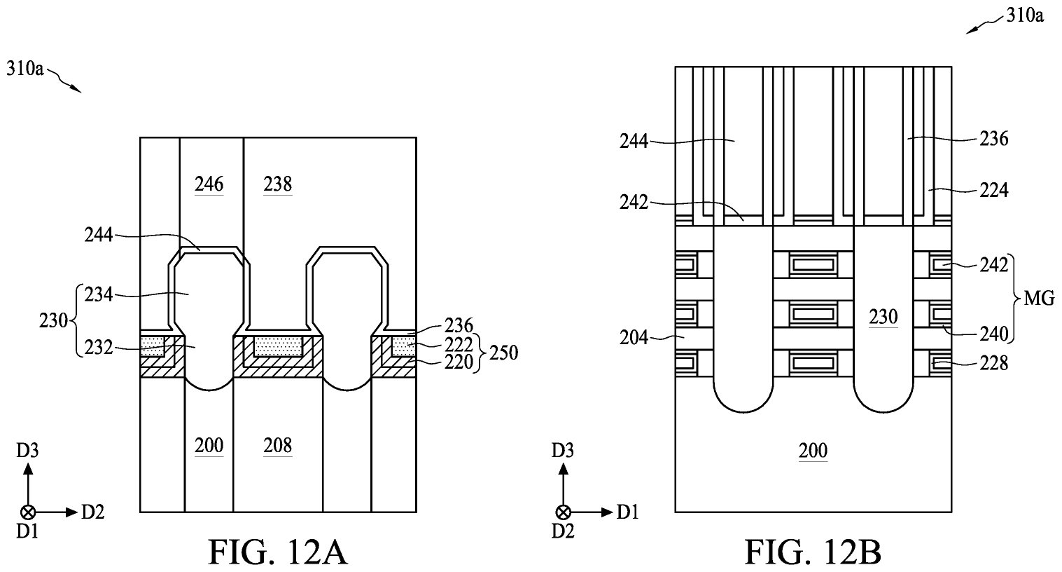

Please refer to FIGS. 12A and 12B, which are cross-sectional views of a semiconductor structure 310a according to some embodiments of the present disclosure. In some embodiments, after the forming of the epitaxial source/drain structures 230, a contact etch-stop layer (CESL) 236 can be formed to cover the sacrificial gate structures 210 over the substrate 200. In some embodiments, the CESL 236 can include silicon nitride, silicon oxynitride, and/or other applicable materials. Subsequently, an inter-layer dielectric (ILD) layer 238 can be formed on the CESL 236 over the substrate 200 in accordance with some embodiments. The ILD layer 238 may include multilayers made of multiple dielectric materials, such as silicon oxide, silicon nitride, silicon oxynitride, tetraethoxysilane (TEOS), phosphosilicate glass (PSG), borophosphosilicate glass (BPSG), low-k dielectric material, and/or other applicable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), and polyimide. Next, a polishing process is performed on the ILD layer 238, the CESL 236 and the patterned hard mask 213/215 to expose top surfaces of the polysilicon layer 212 of the sacrificial gate structures 210. In some embodiments, the ILD layer 238 and the CESL 236 are planarized by a CMP process until the top surfaces of the polysilicon layer 212 are exposed.

In some embodiments, an operation that replaces the sacrificial gate structure 210 with a metal gate structure is performed. In some embodiments, the polysilicon layer 212 is removed to form gate trenches (not shown) with the spacers 224 exposed through sidewalls of the gate trenches. Subsequently, portions of the nanosheet stack fin 202 are removed. In some embodiments, the semiconductor layers 206 are removed such that the semiconductor layers 204 remain and are separate from each other in the gate trenches, and the remaining semiconductor layers 204 are referred to as nanosheets 204. In some embodiments, the nanosheets 204 remaining in the gate trenches are trimmed. In such embodiments, each of the nanosheets 204 is trimmed to have a desired shape and desired dimensions (i.e., thickness and width). By adjusting the width and the thickness of the nanosheets 204, a threshold voltage (Vt) of a FET device to be formed can be adjusted to meet requirements.

Still referring to FIGS. 12A and 12B, in some embodiments, an interfacial layer (IL) (not shown) may be formed over each of the nanosheets 204, and a high-k gate dielectric layer 240 is formed over the IL to surround each of the nanosheets 204. In some embodiments, the high-k gate dielectric layer 240 includes a high-k dielectric material having a high dielectric constant, for example, a dielectric constant greater than that of thermal silicon oxide (^{˜}3.9). The high-k dielectric material may include hafnium oxide (HfO₂), zirconium oxide (ZrO₂), lanthanum oxide (La₂O₃), aluminum oxide (Al₂O₃), titanium oxide (TiO₂), yttrium oxide (Y₂O₃), strontium titanate (SrTiO₃), hafnium oxynitride (HfOₓN_{y}), other suitable metal-oxides, or combinations thereof.

In some embodiments, a gate electrode layer 242 is formed over the high-k gate dielectric layer 240. The gate electrode layer 242 may include a plurality of metal layers, though not shown. The gate electrode layer 242 may include a work function metal layer, a gap-filling metal layer, and/or other conductive layers, depending on product designs. Further, the IL, the high-k gate dielectric layer 240 and the gate electrode layer 242 form a metal gate structure MG.

Accordingly, a semiconductor structure 310a is formed. The semiconductor structure 310a includes the isolation structure 208 in the substrate 200, and the metal gate structure MG. In some embodiments, the isolation structure 208 extends in the first direction D1, and the metal gate structure MG extends in the second direction D2. The metal gate structure MG may be disposed over a portion of the isolation structure 208. As shown in FIG. 12B, the semiconductor structure 310a includes a plurality of nanosheets 204 separated from each other over the substrate 200. The metal gate structure MG (i.e., the high-k gate dielectric layer 240 and the gate electrode layer 242) surrounds each of the nanosheets 204.

The semiconductor structure 310a further includes the spacer 224 disposed over sidewalls of the metal gate structure MG, and the epitaxial source/drain 230 disposed at two sides of the metal gate structure MG. Further, the semiconductor structure 310a includes a protection structure 250, which includes the first dielectric layer 220 and the second dielectric layer 222. The first dielectric layer 220 and the second dielectric layer 222 include different materials, while the first dielectric layer 220 and the spacer 224 include a same material. In some embodiments, a thickness of the first dielectric layer 220 and a thickness of the spacer 224 are equal. In some embodiments, the thickness of the first dielectric layer 220 is less than a thickness of the second dielectric layer 222. Further, the first dielectric layer 220 includes a U shape. In some embodiments, a top surface of the protection structure 250 is lower than top surfaces of the epitaxial source/drain structures 230.

In some embodiments, the semiconductor structure 310a further includes the CESL 236 and the ILD layer 238. As shown in FIG. 12A, the CESL 236 is in contact with a portion of the epitaxial source/drain structure 230 and a top surface of the protection structure 250. That is, the CESL 236 is in contact with a topmost surface of the first dielectric layer 220 and the top surface of the second dielectric layer 222. In some embodiments, a top surface of the ILD layer 238 is aligned with or level with a top surface of the metal gate structure MG. In some embodiments, the semiconductor structure 310a further includes a salicide layer 244 and a connecting structure such as a contact via 246.

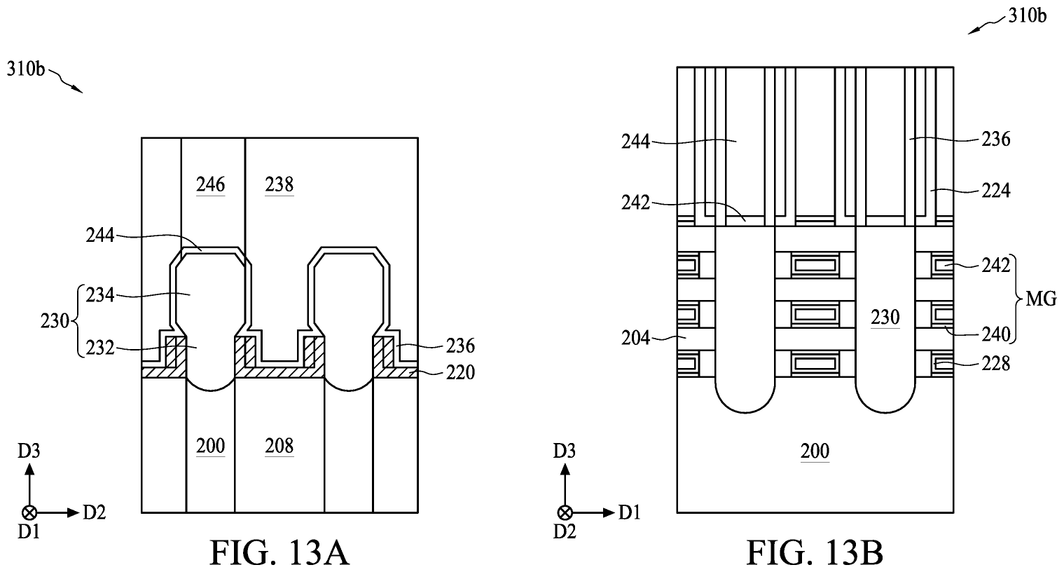

Please refer to FIGS. 13A and 13B, which are cross-sectional views of a semiconductor structure 310b according to some embodiments of the present disclosure. In some embodiments, the semiconductor structure 310b is provided. The semiconductor structure 310b includes the isolation structure 208 disposed in the substrate 200, the metal gate structure MG disposed over the substrate 200, the spacer 224 disposed over the sidewalls of the metal gate structure MG, the epitaxial source/drain structures 230 disposed at the two sides of the metal gate structure MG, and a protection layer (i.e., the first dielectric layer 220) disposed over the isolation structure 208. In such embodiments, the protection layer 220 and the spacer 224 have a same material and a same thickness. Further, the protection layer 220 includes a U shape. Details of the isolation structure 208, the metal gate structure MG, the spacer 224 and the epitaxial source/drain structures 230 may be similar to those described above; therefore, details thereof are omitted for brevity.

In some embodiments, the semiconductor structure 310b further includes the CESL 236, the ILD layer 238, the salicide layer 244 and the connecting structure 246. In some embodiments, the CESL 236 is conformally formed over the protection layer 220. That is, the CESL 236 is in contact with a top surface of the U-shaped protection layer 220.

Accordingly, the present disclosure therefore provides a semiconductor structure and a method for forming the same. In some embodiments, the method includes forming a protection layer or a protection structure over an isolation structure, such that the isolation structure is protected from consumption or damage during forming of a recess for accommodating epitaxial source/drain structures. Accordingly, an isolation loss issue is mitigated, and potential risks of poly collapse and improper epitaxial structure are reduced.

According to one embodiment of the present disclosure, a semiconductor structure is provided. The semiconductor structure includes an isolation structure in a substrate, a metal gate structure over the substrate and a portion of the isolation structure, a spacer at sidewalls of the metal gate structure, epitaxial source/drain structure at two sides of the metal gate structure, and a protection layer over the isolation structure. The protection layer and the spacer include a same material.

According to one embodiment of the present disclosure, a semiconductor structure is provided. The semiconductor structure includes an isolation structure in a substrate, a metal gate structure over the substrate and a portion of the isolation structure, a spacer at sidewalls of the metal gate structure, epitaxial source/drain structure at two sides of the metal gate structure, and a protection structure over the isolation structure. The protection structure includes a first dielectric layer and a second dielectric layer. The first dielectric layer and the second dielectric layer include different materials. The first dielectric layer and the spacer include a same material.

According to one embodiment of the present disclosure, a method for forming a semiconductor structure is provided. The method includes following operations. A nanosheet stack fin is formed over a substrate. An isolation structure is formed at two sides of the nanosheet stack fin. A sacrificial gate structure is formed over the nanosheet stack fin. The nanosheet stack fin extends in a first direction, and the sacrificial gate structure extends in a second direction different from the first direction. A first dielectric layer is formed over the sacrificial gate structure and the nanosheet stack fin. A second dielectric layer is formed over the first dielectric layer. Portions of the second dielectric layer are removed to expose the first dielectric layer over the sacrificial gate structure. Portions of the first dielectric layer and portions of the nanosheet stack fin at two sides of the sacrificial gate structure are removed to form a plurality of recesses. Epitaxial source/drain structures are formed in the recesses.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
an isolation structure in a substrate;
a metal gate structure over the substrate and a portion of the isolation structure;
a spacer at sidewalls of the metal gate structure;
epitaxial source/drain structures at two sides of the metal gate structure; and
a protection layer over the isolation structure,
wherein the protection layer and the spacer comprise a same material.

2. The semiconductor structure of claim 1, further comprising:
a plurality of nanosheets separated from each other over the substrate; and
a high-k gate dielectric layer surrounding each of the nanosheets,
wherein the metal gate structure surrounds the plurality of nanosheets and the high-k gate dielectric layer.

3. The semiconductor structure of claim 1, wherein a thickness of the spacer and a thickness of the protection layer are equal.

4. The semiconductor structure of claim 1, wherein the protection layer has a U shape.

5. The semiconductor structure of claim 1, further comprising a contact etch stop layer (CESL) over the substrate, wherein the CESL is in direct contact with the protection layer.

6. The semiconductor structure of claim 1, wherein a top surface of the protection layer is lower than top surfaces of the epitaxial source/drain structures.

7. A semiconductor structure comprising:
an isolation structure in a substrate;
a metal gate structure over the substrate and a portion of the isolation structure;
a spacer at sidewalls of the metal gate structure;
epitaxial source/drain structures disposed at two sides of the metal gate structure; and
a protection structure over the isolation structure, wherein the protection structure comprises:
a first dielectric layer; and
a second dielectric layer over the first dielectric layer, wherein the first dielectric layer and the second dielectric layer comprise different materials, and the first dielectric layer and the spacer comprise a same material.

8. The semiconductor structure of claim 7, further comprising:
a plurality of nanosheets separated from each other over the substrate; and
a high-k gate dielectric layer surrounding each of the nanosheets,
wherein the metal gate structure surrounds the plurality of nanosheets and the high-k gate dielectric layer.

9. The semiconductor structure of claim 7, wherein a thickness of the spacer and a thickness of first dielectric layer of the protection structure are equal.

10. The semiconductor structure of claim 9, wherein a thickness of the second dielectric layer is greater than the thickness of the first dielectric layer.

11. The semiconductor structure of claim 7, wherein the first dielectric layer has a U shape.

12. The semiconductor structure of claim 11, further comprising a contact etch stop layer (CESL) over the substrate, wherein the CESL is in direct contact with a top surface of the second dielectric layer and topmost portions of the first dielectric layer.

13. The semiconductor structure of claim 7, wherein a top surface of the protection structure is lower than top surfaces of the epitaxial source/drain structures.

14. A method for forming a semiconductor structure, comprising:
forming a nanosheet stack fin over a substrate;
forming isolation structures at two sides of the nanosheet stack fin;
forming a sacrificial gate structure over the nanosheet stack fin, wherein the nanosheet stack fin extends in a first direction, and the sacrificial gate structure extends in a second direction different from the first direction;
forming a first dielectric layer over the sacrificial gate structure and the nanosheet stack fin;
forming a second dielectric layer over the first dielectric layer;
removing portions of the second dielectric layer to expose portions of the first dielectric layer over the sacrificial gate structure;
removing portions of the first dielectric layer and portions of the nanosheet stack fin at two sides of the sacrificial gate structure to form a plurality of recesses; and
forming epitaxial source/drain structures in the recesses.

15. The method of claim 14, wherein the removing of the portions of the second dielectric layer further comprises:
performing a planarization on the second dielectric layer such that a top surface of the second dielectric layer and a first top surface of the first dielectric layer over the sacrificial gate structure are level; and
performing a first etch-back operation on the second dielectric layer to expose portions of the first dielectric layer over the sacrificial gate structure.

16. The method of claim 15, wherein the top surface of the second dielectric layer is lowered to level with a second top surface of the first dielectric layer over the nanosheet stack fin after the first etch-back operation.

17. The method of claim 14, further comprising performing a second etch-back to remove a portion of the first dielectric layer over the sacrificial gate structure to form a spacer at sidewalls of the sacrificial gate structure.

18. The method of claim 14, wherein bottom surfaces of the recesses are lower than a bottom surface of the first dielectric layer.

19. The method of claim 14, further comprising forming inner spacers prior to the forming of the epitaxial source/drain structures.

20. The method of claim 14, further comprising replacing the sacrificial gate structure with a metal gate structure.
